(19) United States
(12) Patent Application Publication
(10) Pub. No.: US 2018/0331049 A1
(43) Pub. Date: Nov. 15, 2018

(54) CHIP ON FILM PACKAGE

(71) Applicant: Novatek Microelectronics Corp., Hsinchu (TW)

(72) Inventors: Wen-Ching Huang, Hsinchu City (TW); Tai-Hung Lin, Hsinchu City (TW)

(73) Assignee: Novatek Microelectronics Corp., Hsinchu (TW)

(21) Appl. No.: 15/705,264

(22) Filed: Sep. 15, 2017

Related U.S. Application Data
(60) Provisional application No. 62/505,992, filed on May 15, 2017.

(51) Int. Cl. H01L 23/60; H01L 23/498

(52) U.S. Cl. CPC H01L 23/60; H01L 23/49827

(57) ABSTRACT

A chip on film package includes a base film, a patterned circuit layer, a solder resist layer, a chip and a first conductive film. The base film includes a first surface and a mounting region located on the first surface. The patterned circuit layer is disposed on the first surface. The solder resist layer partially covers the patterned circuit layer. The chip is disposed in the mounting region and electrically connected to the patterned circuit layer. The first conductive film covers at least a part of the first solder resist layer and an opening exposing at least a part of the patterned circuit layer, wherein the first conductive film is configured to shield electromagnetic interference (EMI) emanating by the chip and is electrically connected to the patterned circuit layer.

### CROSS-REFERENCE TO RELATED APPLICATION

This application claims the priority benefit of U.S. provisional application Ser. No. 62/505,992, filed on May 15, 2017. The entirety of the above-mentioned patent application is hereby incorporated by reference herein and made a part of this specification.

### BACKGROUND

### Technical Field

The present disclosure generally relates to a chip package. More particularly, the present disclosure relates to a chip on film package.

### Description of Related Art

In semiconductor production, the manufacturing of integrated circuits (IC) can be divided into three different stages, namely, a wafer fabrication stage, an integrated circuit fabrication stage and an IC packaging stage such as applying a chip-on-film (COF) package.

Conventionally, no measures of shielding electromagnetic interference (EMI) have been applied on a COF package. However, increasing problems of electromagnetic interferences happening between various integrated circuits and chips have been observed when the COF package is incorporated with other functions (e.g., touch panel) or applied on small or medium size panels thus confining the space available to assemble and install integrated circuits and chips.

### SUMMARY

Accordingly, the present disclosure is directed to a chip on film package with adequate electromagnetic interference shielding for the integrated circuits and chips assembled and installed therein.

The present disclosure provides a chip on film package includes a base film, a patterned circuit layer, a solder resist layer, a chip and a first conductive film. The base film includes a first surface and a mounting region located on the first surface. The patterned circuit layer is disposed on the first surface. The first solder resist layer partially covers the patterned circuit layer. The chip is disposed in the mounting region and electrically connected to the patterned circuit layer. The first conductive film covers at least a part of the first solder resist layer and an opening exposing at least a part of the patterned circuit layer. The first conductive film is configured to shield electromagnetic interference emanating by the chip and is electrically connected to the patterned circuit layer.

According to an embodiment of the present disclosure, a conductive layer is disposed between the first conductive film and the patterned circuit layer.

According to an embodiment of the present disclosure, the first conductive film is pasting, laminating, coating, or sputtering onto the at least a part of the first solder resist layer and the conductive layer.

According to an embodiment of the present disclosure, the first conductive film is pasting, laminating, coating, or sputtering onto the at least a part of the first solder resist layer and the opening.

According to an embodiment of the present disclosure, the chip on film package further includes a first through hole penetrating the patterned circuit layer and the base film. The opening is aligned with the first through hole.

According to an embodiment of the present disclosure, the chip on film package further includes an electrically conductive coating covering at least a portion of a first sidewall of the opening and at least a portion of a second sidewall of the first through hole.

According to an embodiment of the present disclosure, the chip on film package further includes an electrically conductive coating covering at least a portion of a second sidewall of the first through hole.

According to an embodiment of the present disclosure, the chip on film package further includes an electrically conductive filling filled at least a portion of the first through hole.

According to an embodiment of the present disclosure, the opening is a circle, ellipse, triangle, rectangle, strip, or polygon.

According to an embodiment of the present disclosure, the base film is a polyimide (PI) film.

According to an embodiment of the present disclosure, the chip on film package further includes a metallic layer and a second solder resist layer. The metallic layer is disposed on a second surface of the base film. The second solder resist layer covers a third surface of the metallic layer.

According to an embodiment of the present disclosure, the chip on film package further includes a second through hole penetrating the patterned circuit layer, the base film, the metallic layer, and the second solder resist layer, wherein the opening is aligned with the second through hole.

According to an embodiment of the present disclosure, the chip on film package further includes an electrically conductive coating covering at least a portion of a first sidewall of the opening and at least a portion of a third sidewall of the second through hole.

According to an embodiment of the present disclosure, the chip on film package further includes an electrically conductive coating covering at least a portion of a third sidewall of the second through hole.

According to an embodiment of the present disclosure, the chip on film package further includes an electrically conductive filling filled at least a portion of the second through hole.

According to an embodiment of the present disclosure, the chip on film package further includes a second conductive film. The second conductive film is disposed on a second surface of the base film and is configured to shield electromagnetic interference emanating by the chip.

According to an embodiment of the present disclosure, the chip on film package further includes a third through hole penetrating the patterned circuit layer, the base film, and the second conductive film, wherein the opening is aligned with the third through hole

According to an embodiment of the present disclosure, the chip on film package further includes an electrically conductive coating covering at least a portion of a first sidewall of the opening and a fourth sidewall of the third through hole.

According to an embodiment of the present disclosure, the chip on film package further includes an electrically conductive coating covering a fourth sidewall of the third through hole.

According to an embodiment of the present disclosure, the chip on film package further includes an electrically conductive filling filled the third through hole.

In light of the foregoing, the first conductive film is attached to the chip on film package of the disclosure, covering at least a part of the first solder resist layer and an opening exposing at least a part of the patterned circuit layer. The first conductive film is configured to shield electromagnetic interference emanating by the chip and is electrically connected to the patterned circuit layer. Alternatively, a conductive layer is disposed between the first conductive film and the patterned circuit layer, such that the first conductive film is electrically connected to the patterned circuit layer through the conductive layer. With such configuration, having adequate measures of shielding electromagnetic interference, the COF package can be incorporated with other functions (e.g., touch panel) or be applied on small or medium size panels without having the problems of electromagnetic interferences happening between various integrated circuits and chips, so as to improve the applicability and expand the applications of the chip on film package.

In addition, a metallic layer and a second solder resist layer can be attached to the second surface of the base film of the chip on film package of the disclosure where the integrate circuits or the chips are not installed, along with having a through hole penetrating the entire structure and applying an electrically conductive coating or an electrically conductive filling to the through hole. With such configuration, the electrical conductivity can be advanced thus the shielding of electromagnetic interference is provided on both sides of the base film. Alternatively, the metallic layer and the second solder resist layer can be replaced by a second conductive film that is configured to shield electromagnetic interference emanating between multiple chips on film packages, so the shielding of electromagnetic interference on both sides of the base film of the chip on film package in the disclosure can be further improved.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1A illustrates a cross-sectional view of a chip on film package according to an embodiment of the disclosure.

FIG. 1B illustrates a cross-sectional view of a chip on film package according to another embodiment of the disclosure.

FIG. 1C illustrates a cross-sectional view of a chip on film package according to another embodiment of the disclosure.

FIG. 1D illustrates a cross-sectional view of a chip on film package according to another embodiment of the disclosure.

FIG. 1E illustrates a cross-sectional view of a chip on film package according to another embodiment of the disclosure.

FIG. 2A illustrates a top view of a chip on film package according to an embodiment of the disclosure.

FIG. 2B illustrates a top view of a chip on film package according to another embodiment of the disclosure.

FIG. 3A illustrates a cross-sectional view of a chip on film package according to another embodiment of the disclosure.

FIG. 3B illustrates a cross-sectional view of a chip on film package according to another embodiment of the disclosure.

FIG. 3C illustrates a cross-sectional view of a chip on film package according to another embodiment of the disclosure.

FIG. 4A illustrates a cross-sectional view of a chip on film package according to another embodiment of the disclosure.

FIG. 4B illustrates a cross-sectional view of a chip on film package according to another embodiment of the disclosure.

FIG. 4C illustrates a cross-sectional view of a chip on film package according to another embodiment of the disclosure.

### DESCRIPTION OF THE EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

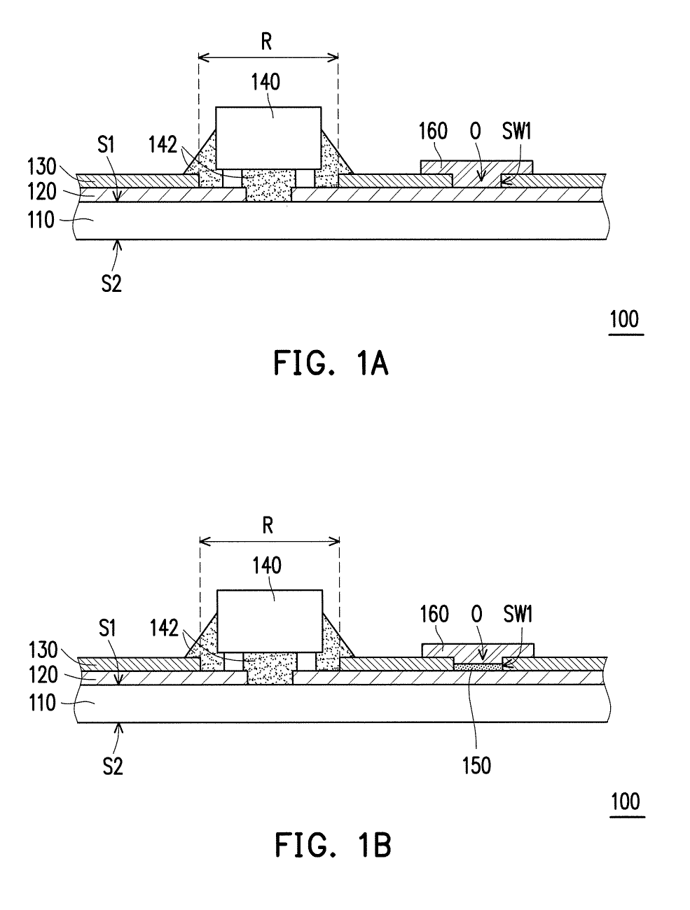

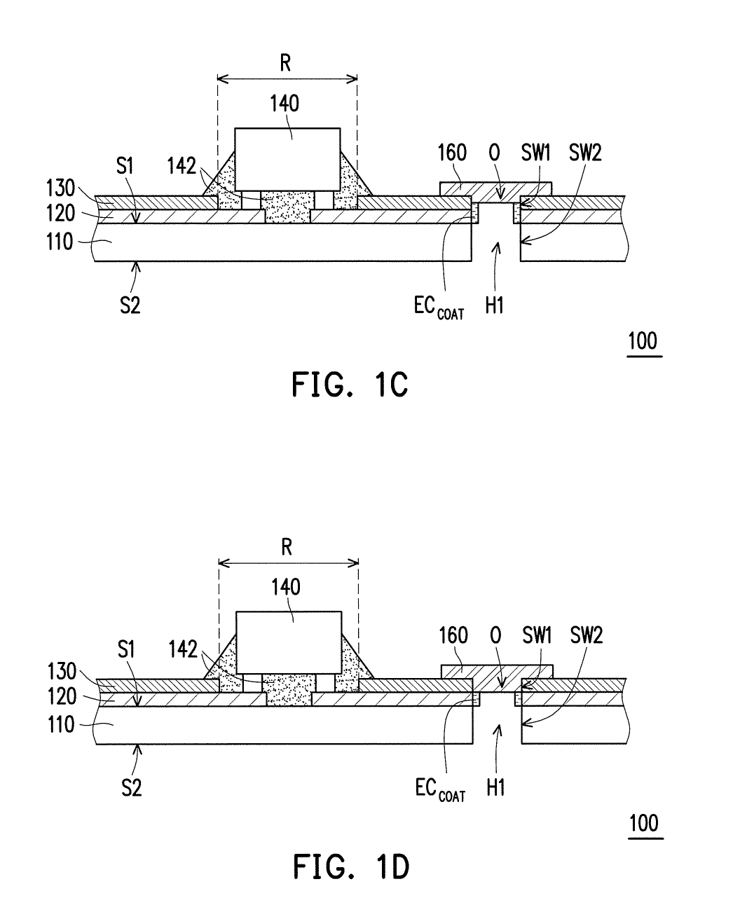

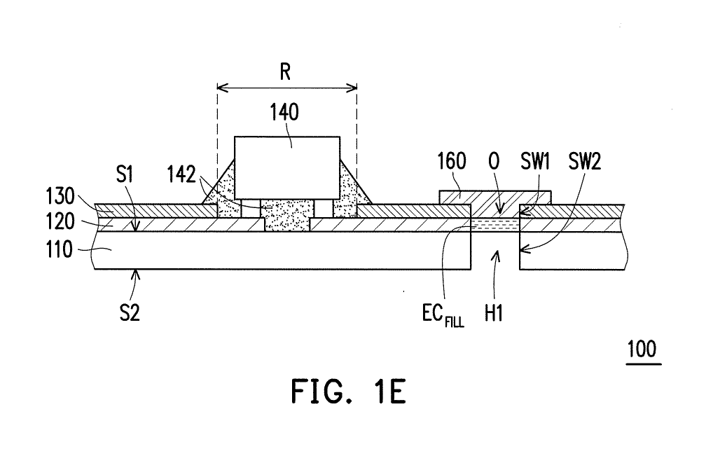

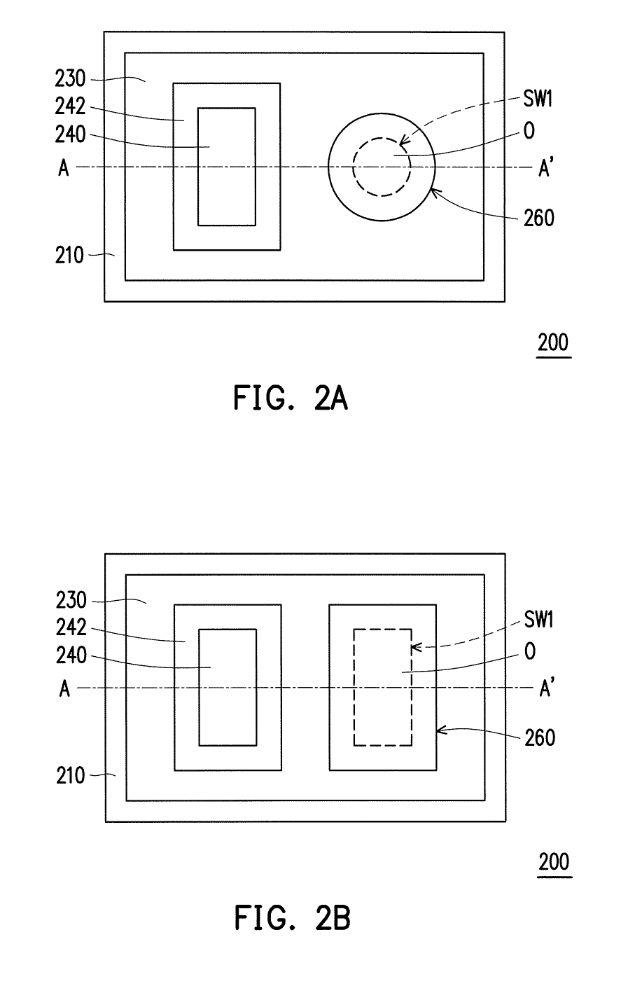

FIGS. 1A to 1E each illustrates a cross-sectional view of a chip on film package according to an embodiment of the disclosure. FIGS. 2A to 2B each illustrates a top view of a chip on film package according to an embodiment of the disclosure. It is noted that each of FIGS. 1A to 1E is the cross-sectional view of any of FIGS. 2A to 2B along line A-A′.

Referring to FIG. 1A, in the present embodiment, a chip on film package 100 includes a base film 110, a patterned circuit layer 120, a first solder resist layer 130, a chip 140 and a first conductive film 160. The base film 110 includes a first surface S1 and a mounting region R located on the first surface S1. The patterned circuit layer 120 is disposed on the first surface S1 of the base film 110. The first solder resist layer 130 partially covers the patterned circuit layer 120. The chip 140 is disposed in the mounting region R and electrically connected to the patterned circuit layer 120. The first conductive film 160 covers the first solder resist layer 130. The base film 110 can be made by phenol formaldehyde resin (PF), epoxy resin, polyester resin, bismaleimide modified triazine resin (BT), polyimide resin (PI), diphenylene ether resin (PPO), maleic anhydride imide-styrene resin (MS), polycyclic ester resin, polyolefin resin, and the likes. In the present embodiment, the base film 110 is preferably made by polyimide resin (PI). In the present embodiment, the first solder resist layer 130 covers the patterned circuit layer 120 and has an opening O exposing a part of the patterned circuit layer 120, such that the first conductive film 160 is electrically connected to the part of the patterned circuit layer 120 exposed by the first solder resist layer 130 through the opening O. In the present embodiment, the first conductive film 160 is configured to shield electromagnetic interference emanating by the chip 140 through the electromagnetic wave absorptive particles therein. In addition, the first conductive film 160 is pasting, laminating, coating, or sputtering onto the at least a part of the first solder resist layer 130 and the opening O. In the present embodiment, the patterned circuit layer 120 is extended to the mounting region R and the first solder resist layer 130 exposes a part of the patterned circuit layer 120 extended to the mounting region R as shown in FIG. 1A. The chip 140 is mounted on the part of the patterned circuit layer 120 extended to the mounting region R. In addition, the chip on film package 100 may further include an underfill 142 filled between the chip 120 and the base film 110, and the patterned circuit layer 120 extended to the mounting region R exposing by the first solder resist layer 130 as shown in FIG. 1A.

Referring to FIG. 1B, in the present embodiment, the structure is similar to the embodiment shown in FIG. 1A. The difference is a conductive layer 150 is disposed in the opening O, and between the first conductive film 160 and the patterned circuit layer 120. The first conductive film 160 is pasting, laminating, coating, or sputtering onto the at least a part of the first solder resist layer 130 and the conductive layer 150. The first conductive film 160 is electrically connected to the part of the patterned circuit layer 120 exposed by the first solder resist layer 130 through the conductive layer 150. In the present embodiment, the conductive layer 150 only fills a half of the opening O. In other embodiments, the conductive layer 150 can also fully fill the opening O, or fill any portion of the opening O or just apply as a thin coating between the first conductive film 160 and the patterned circuit layer 120. The disclosure is not limited thereto. Therefore, the electrical connection between the first conductive film 160 and the patterned circuit layer 120 is either advanced or ensured, such that the first conductive film 160 can properly and effectively shield electromagnetic interference emanating by the chip 140.

Referring to FIGS. 1C to 1E, in these embodiments, the structures are similar to the embodiment shown in FIG. 1A. The major difference between FIGS. 1C to 1E and FIG. 1A is that the chip on film package 100 further includes a first through hole H1 penetrating the patterned circuit layer 120 and the base film 110, wherein the opening O is aligned with the first through hole H1 as shown in FIG. 1C-1E.

Referring to FIG. 1C, in the present embodiment, an electrically conductive coating EC_{COAT} covers a first sidewall SW1 of the opening O and a second sidewall SW2 of the first through hole H1. In the present embodiment, the electrically conductive coating EC_{COAT} only covers a half of both first sidewalls SW1 of the opening O and the entire of both second sidewall SW2 of the first through hole H1. The remaining half of the opening O is pasted, laminated, coated, or sputtered by the first conductive film 160 as shown in FIG. 1C. In other embodiments, the electrically conductive coating EC_{COAT} can cover any portion of either single or both first sidewall SW1 of the opening O, and any portion of either single or both second sidewall SW2 of the first through hole H1. The remaining portion of the opening O is pasted, laminated, coated, or sputtered by the first conductive film 160 accordingly. The disclosure is not limited thereto.

Referring to FIGS. 1D to 1E, in the present two embodiments, an electrically conductive coating EC_{COAT} covers a second sidewall SW2 of the first through hole H1, or an electrically conductive filling EC_{FILL} fills the first through hole H1. In the embodiment shown in FIG. 1D, the electrically conductive coating EC_{COAT} covers the entire of both second sidewall SW2 of the first through hole H1. In the embodiment shown in FIG. 1E, the electrically conductive filling EC_{FILL} fills only the portion of the first through hole H1 where the patterned circuit layer 120 is penetrated. In other embodiments, the electrically conductive coating EC_{COAT} can cover any portion of either single or both second sidewall SW2 of the first through hole H1. Alternatively, the electrically conductive filling EC_{FILL} can fill any portion of the first through hole H1. In addition, embodiments of using the electrically conductive coating EC_{COAT} and the electrically conductive filling EC_{FILL} can be incorporated in any ratio. The disclosure is not limited thereto.

In various embodiments shown in FIGS. 1C to 1E, the opening O serving as part of the channel electrically connecting the first conductive film 160 and the patterned circuit layer 120 is covered by the first conductive film 160 as also shown in FIG. 1A. Alternatively, the patterned circuit layer 120 can be covered by both of the first conductive film 160 and the conductive layer 150 in any ratio, for example fifty percent (50%) of each as also shown in FIG. 1B. The disclosure is not limited thereto.

Therefore, the electrical connection between the first conductive film 160 and the patterned circuit layer 120 is either advanced or ensured, such that the first conductive film 160 can properly and effectively shield electromagnetic interference emanating by the chip 140.

Referring to FIGS. 2A to 2B, in these embodiments, the opening O viewing from the top of the chip on film package 200 is a circle, ellipse, triangle, square, rectangle, strip, or polygon as illustrated in FIGS. 2A to 2B, but the disclosure is not limited thereto. As such, the shape of the opening O can be made in accordance to the electromagnetic interference emanation and the energy consumption by, or the shape of the chip 240; such structural flexibility can also benefit multiple chips 240 disposed near each other to render the best shielding effect of the first conductive film 260.

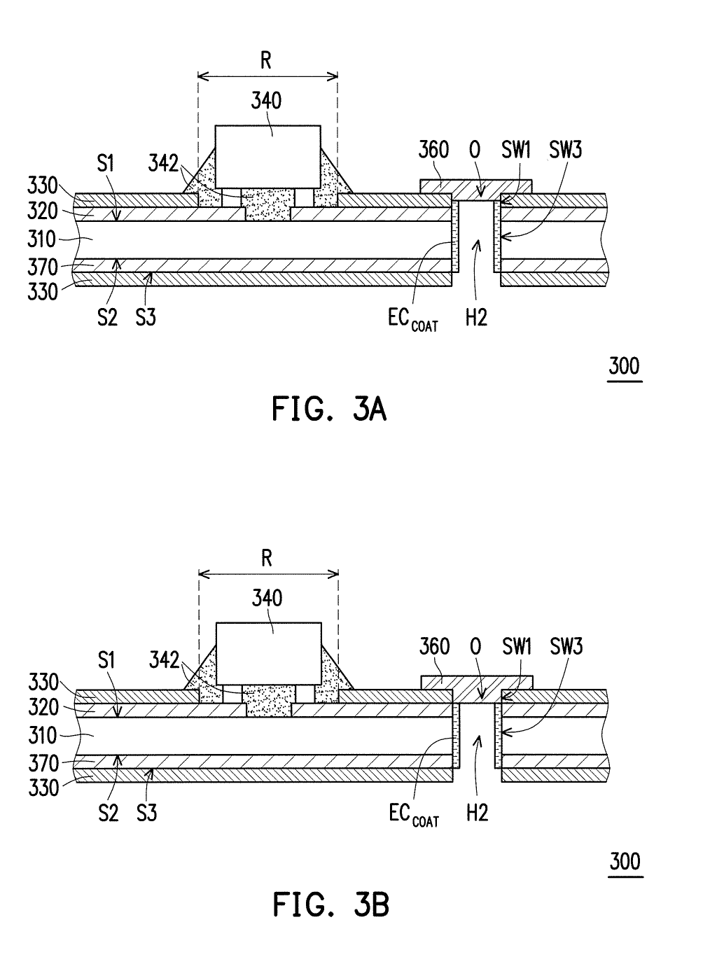

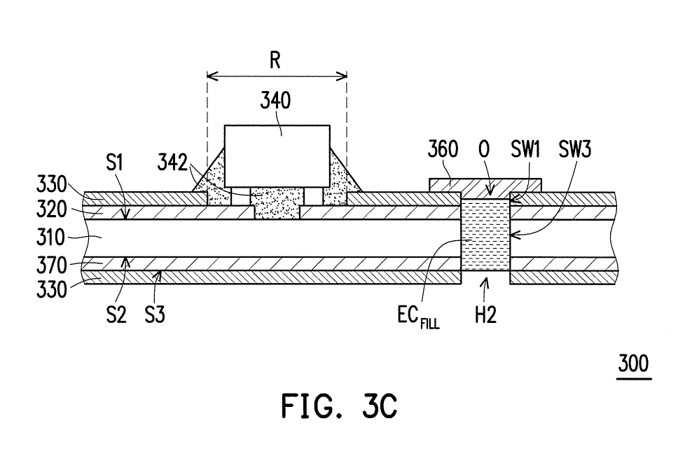

Referring to FIGS. 3A to 3C, in these embodiments, the structures are similar to the embodiment shown in FIG. 1A. The major difference between FIGS. 3A to 3C and FIG. 1A is that the chip on film package 300 further includes a metallic layer 370, a second solder resist layer 330, and a second through hole H2. The metallic layer 370 is disposed on a second surface S2 of the base film 310. The second solder resist layer 330 covers a third surface S3 of the metallic layer 370. The second through hole H2 penetrating the patterned circuit layer 320, the base film 310, the metallic layer 370, and the second solder resist layer 330, where the opening O is aligned with the second through hole H2 as shown in FIGS. 3A to 3C.

Referring to FIG. 3A, in the present embodiment, an electrically conductive coating EC_{COAT} covers a first sidewall SW1 of the opening O and a third sidewall SW3 of the second through hole H2. In the present embodiment, the electrically conductive coating EC_{COAT} only covers a half of both first sidewalls SW1 of the opening O, and the patterned circuit layer 320, the base film 310, and the metallic layer 370 portions of both third sidewall SW3 of the second through hole H2. The remaining half of the opening O is pasted, laminated, coated, or sputtered by the first conductive film 360 as shown in FIG. 3A. In other embodiments, the electrically conductive coating EC_{COAT} can cover any portion of single side of first sidewall SW1 of the opening O, and at least the same side of the patterned circuit layer 320, the base film 310, and the metallic layer 370 portions third sidewall SW3 of the second through hole H2. The remaining portion of the opening O is pasted, laminated, coated, or sputtered by the first conductive film 360 accordingly. The disclosure is not limited thereto.

Referring to FIGS. 3B to 3C, in the present two embodiments, an electrically conductive coating EC_{COAT} covers a third sidewall SW3 of the second through hole H2, or an electrically conductive filling EC_{FILL} fills the second through hole H2. In the embodiment shown in FIG. 3B, the electrically conductive coating EC_{COAT} covers the entire of both third sidewall SW3 of the second through hole H2. In the embodiment shown in FIG. 3C, the electrically conductive filling EC_{FILL} fills only portions of the second through hole H2 where the patterned circuit layer 320, the base film 310, and the metallic layer 370 are penetrated. In other embodiments, the electrically conductive coating EC_{COAT} can cover at least one side of the patterned circuit layer 320, the base film 310, and the metallic layer 370 portions of third sidewall SW3 of the second through hole H2. Alternatively, the electrically conductive filling EC_{FILL} can fill the entire of the second through hole H2. In addition, embodiments of using the electrically conductive coating EC_{COAT} and the electrically conductive filling EC_{FILL} can be incorporated in any ratio. The disclosure is not limited thereto.

In various embodiments shown in FIGS. 3A to 3C, the opening O serving as part of the channel electrically connecting the first conductive film 360 and the patterned circuit layer 320 is covered by the first conductive film 360 as previously illustrated in FIG. 1A. Alternatively, the patterned circuit layer 320 can be covered by both of the first conductive film 360 and the conductive layer 350 in any ratio, for example fifty percent (50%) of each as previously illustrated in FIG. 1B. The disclosure is not limited thereto.

Therefore, not only the electrical connection between the first conductive film 360 and the patterned circuit layer 320 is either advanced or ensured, the electrical connection between the first conductive film 360 and the metallic layer 370 is also advanced or ensured. The first conductive film 360 can properly and effectively shield electromagnetic interference emanating by the chip 340, and the metallic layer 370 can properly and effectively shield electromagnetic interference emanating between multiple chips on film packages 300. As such, the shielding of electromagnetic interference on both sides of the base film 310 of the chip on film package 300 in the disclosure can be further improved.

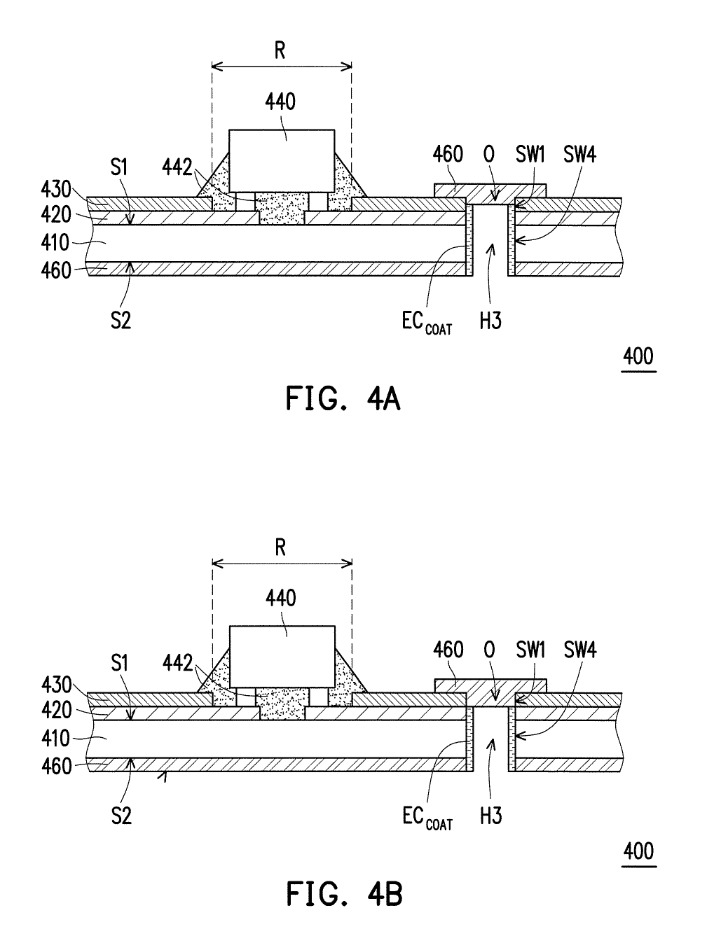

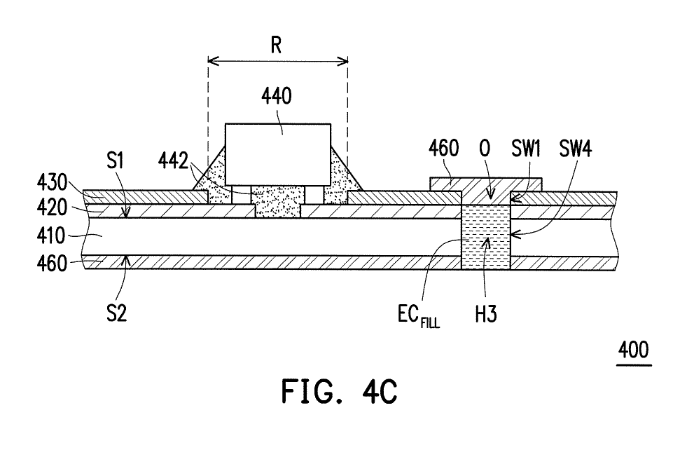

Referring to FIGS. 4A to 4C, in these embodiments, the structures are similar to the embodiment shown in FIG. 1A. The major difference between FIGS. 4A to 4C and FIG. 1A is that the chip on film package 400 further includes a second conductive film 460 and a third through hole H3. The second conductive film 460 is disposed on a second surface S2 of the base film 410. The third through hole H3 penetrating the patterned circuit layer 420, the base film 410, and second conductive film 460, where the opening O is aligned with the third through hole H3 as shown in FIGS. 4A to 4C. In the present embodiment, the second conductive film 460 is configured to shield electromagnetic interference emanating by the chip 440 through the electromagnetic wave absorptive particles therein.

Referring to FIG. 4A, in the present embodiment, an electrically conductive coating EC_{COAT} covers a first sidewall SW1 of the opening O and a fourth sidewall SW4 of the third through hole H3. In the present embodiment, the electrically conductive coating EC_{COAT} only covers a half of both first sidewalls SW1 of the opening O, and the entire of both fourth sidewall SW4 of the third through hole H3. The remaining half of the opening O is pasted, laminated, coated, or sputtered by the first conductive film 460 as shown in FIG. 4A. In other embodiments, the electrically conductive coating EC_{COAT} can cover any portion of single side of first sidewall SW1 of the opening O, and at least the same side of the fourth sidewall SW4 of the third through hole H3. The remaining portion of the opening O is pasted, laminated, coated, or sputtered by the first conductive film 460 accordingly. The disclosure is not limited thereto.

Referring to FIGS. 4B to 4C, in the present two embodiments, an electrically conductive coating EC_{COAT} covers a fourth sidewall SW4 of the third through hole H3, or an electrically conductive filling EC_{FILL} fills the third through hole H3. In the embodiment shown in FIG. 4B, the electrically conductive coating EC_{COAT} covers the entire of both fourth sidewall SW4 of the third through hole H3. In the embodiment shown in FIG. 4C, the electrically conductive filling EC_{FILL} fills the entire of third through hole H3. In other embodiments, the electrically conductive coating EC_{COAT} can cover at least one side of the fourth sidewall SW4 of the third through hole H3. In addition, embodiments of using the electrically conductive coating EC_{COAT} and the electrically conductive filling EC_{FILL} can be incorporated in any ratio. The disclosure is not limited thereto.

In various embodiments shown in FIGS. 4A to 4C, the opening O serving as part of the channel electrically connecting the first conductive film 460 and the patterned circuit layer 420 is covered by the first conductive film 460 as previously illustrated in FIG. 1A. Alternatively, the patterned circuit layer 420 can be covered by both of the first conductive film 460 and the conductive layer 450 in any ratio, for example fifty percent (50%) of each as previously illustrated in FIG. 1B. The disclosure is not limited thereto.

Therefore, not only the electrical connection between the first conductive film 460 and the patterned circuit layer 420 is either advanced or ensured, the electrical connection between the second conductive film 460 and the patterned circuit layer 420 is also advanced or ensured. The first conductive film 460 can properly and effectively shield electromagnetic interference emanating by the chip 440, and second conductive film 460 can properly and effectively shield electromagnetic interference emanating between multiple chips on film packages 400. As such, the shielding of electromagnetic interference on both sides of the base film 410 of the chip on film package 400 in the disclosure can be further improved.

In sum, in the disclosure, the first conductive film graphite sheet is attached to the chip on film package of the disclosure, covering at least a part of the first solder resist layer and an opening exposing at least a part of the patterned circuit layer. The first conductive film is configured to shield electromagnetic interference emanating by the chip and is electrically connected to the patterned circuit layer. Alternatively, a conductive layer is disposed between the first conductive film and the patterned circuit layer, such that the first conductive film is electrically connected to the patterned circuit layer through the conductive layer. With such configuration, having adequate measures of shielding electromagnetic interference, the COF package can be incorporated with other functions (e.g., touch panel) or be applied on small or medium size panels without having the problems of electromagnetic interferences happening between various integrated circuits and chips, so as to improve the applicability and expand the applications of the chip on film package.

In addition, a metallic layer and a second solder resist layer can be attached to the second surface of the base film of the chip on film package of the disclosure where the integrate circuits or the chips are not installed, along with having a through hole penetrating the entire structure and applying an electrically conductive coating or an electrically conductive filling to the through hole. With such configuration, the electrical conductivity can be advanced thus the shielding of electromagnetic interference is provided on both sides of the base film. Alternatively, the metallic layer and the second solder resist layer can be replaced by a second conductive film that is configured to shield electromagnetic interference emanating between multiple chips on film packages, so the shielding of electromagnetic interference on both sides of the base film of the chip on film package in the disclosure can be further improved.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

What is claimed is:

1. A chip on film package, comprising:
a base film comprising a first surface and a mounting region located on the first surface;
a patterned circuit layer disposed on the first surface;
a first solder resist layer partially covering the patterned circuit layer;
a chip disposed in the mounting region and electrically connected to the patterned circuit layer; and
a first conductive film, configured to shield electromagnetic interference emanating by the chip, covering at least a part of the first solder resist layer and an opening exposing at least a part of the patterned circuit layer, wherein the first conductive film is electrically connected to the patterned circuit layer.

2. The chip on film package as claimed in claim 1, wherein a conductive layer is disposed between the first conductive film and the patterned circuit layer.

3. The chip on film package as claimed in claim 2, wherein the first conductive film is pasting, laminating, coating, or sputtering onto the at least a part of the solder resist layer and the conductive layer.

4. The chip on film package as claimed in claim 1, wherein the first conductive film is pasting, laminating, coating, or sputtering onto the at least a part of the first solder resist layer and the opening.

5. The chip on film package as claimed in claim 1, further comprising a first through hole penetrating the patterned circuit layer and the base film, wherein the opening is aligned with the first through hole.

6. The chip on film package as claimed in claim 5, further comprising an electrically conductive coating covering at least a portion of a first sidewall of the opening and at least a portion of a second sidewall of the first through hole.

7. The chip on film package as claimed in claim 5, further comprising an electrically conductive coating covering at least a portion of a second sidewall of the first through hole.

8. The chip on film package as claimed in claim 5, further comprising an electrically conductive filling filled at least a portion of the first through hole.

9. The chip on film package as claimed in claim 1, wherein the opening is a circle, ellipse, triangle, square, rectangle, strip, or polygon.

10. The chip on film package as claimed in claim 1, wherein the base film is a polyimide film.

11. The chip on film package as claimed in claim 1, further comprising:
a metallic layer, disposed on a second surface of the base film; and
a second solder resist layer covering a third surface of the metallic layer.

12. The chip on film package as claimed in claim 11, further comprising a second through hole penetrating the patterned circuit layer, the base film, the metallic layer, and the second solder resist layer, wherein the opening is aligned with the second through hole.

13. The chip on film package as claimed in claim 12, further comprising an electrically conductive coating covering at least a portion of a first sidewall of the opening and at least a portion of a third sidewall of the second through hole.

14. The chip on film package as claimed in claim 12, further comprising an electrically conductive coating covering at least a portion of a third sidewall of the second through hole.

15. The chip on film package as claimed in claim 12, further comprising an electrically conductive filling filled at least a portion of the second through hole.

16. The chip on film package as claimed in claim 1, further comprising:
a second conductive film, configured to shield electromagnetic interference emanating by the chip, disposed on a second surface of the base film.

17. The chip on film package as claimed in claim 16, further comprising a third through hole penetrating the patterned circuit layer, the base film, and the second conductive film, wherein the opening is aligned with the third through hole.

18. The chip on film package as claimed in claim 17, further comprising an electrically conductive coating covering at least a portion of a first sidewall of the opening and a fourth sidewall of the third through hole.

19. The chip on film package as claimed in claim 17, further comprising an electrically conductive coating covering a fourth sidewall of the third through hole.

20. The chip on film package as claimed in claim 17, further comprising an electrically conductive filling filled the third through hole.
